(19) United States
(12) Patent Application Publication
(10) Pub. No.: US 2025/0089429 A1
(43) Pub. Date: Mar. 13, 2025

(54) LED ARRAYS WITH DBR

(71) Applicant: Snap Inc., Santa Monica, CA (US)

(72) Inventor: Tao Wang, Sheffield (GB)

(21) Appl. No.: 18/954,133

(22) Filed: Nov. 20, 2024

Related U.S. Application Data
(63) Continuation of application No. 17/597,699, filed on Jan. 19, 2022, now abandoned.

(30) Foreign Application Priority Data
Jul. 19, 2019 (GB) 1910352.2

(51) Int. Cl. H01L 27/15; H01L 33/00; H01L 33/08; H01L 33/32; H01L 33/60

(52) U.S. Cl. CPC H10H 29/142; H10H 20/813; H10H 20/856; H10H 20/01335; H10H 20/0137; H10H 20/825

(57) ABSTRACT

A method of producing a light emitting diode (LED) array comprises: forming a plurality of layers of semiconductor material; forming a dielectric mask layer over the plurality of layers, the dielectric mask layer having an array of holes through it each exposing an area of one of the layers of semiconductor material, and growing an LED structure in each of the holes arranged to emit light over a range of wavelengths. At least some of the plurality layers form a distributed Bragg reflector (DBR) arranged to reflect light of at least some of said range of wavelengths.

### CLAIM OF PRIORITY

This application is a continuation of U.S. patent application Ser. No. 17/597,699, filed on Jan. 19, 2022, which is a U.S. national-phase application filed under 35 U.S.C. § 371 from International Application Serial No. PCT/EP2020/069917, filed on Jul. 14, 2020, and published as WO 2021/013642 on Jan. 28, 2021, which claims the benefit of priority to United Kingdom Patent Application Serial No. 1910352.2, filed on Jul. 19, 2019, each of which is incorporated herein by reference in its entirety.

### FIELD OF THE INVENTION

The present invention relates to light emitting diode (LED) arrays and to methods of producing LED arrays. In particular, but not exclusively, it relates to arrays of LEDs on the micrometer scale.

### BACKGROUND TO THE INVENTION

There is a significantly increasing demand on developing Group III-nitride light emitting diodes (LEDs) on a micrometre scale, namely, micro-sized LEDs (μLEDs), the key components for new generation displays and visible light communication (VLC) applications. III-nitride μLEDs exhibit a number of unique features for display applications compared with organic light-emitting diodes (OLEDs) and liquid crystal display (LCD). Unlike LCD, III-nitride micro-displays, where μLEDs are the major components, are self-emissive. Monochromatic displays using μLEDs exhibit high resolution, high efficiency, and high contrast ratio. OLEDs are typically operated at a current density which is several orders of magnitude lower than semiconductor LEDs in order to maintain a reasonable lifetime. As a consequence, the luminance of OLEDs is pretty low, typically 3000 cd/m² for a full colour display, while III-nitride μLEDs exhibit high luminance of above 10⁵ cd/m². Of course, III-nitride μLEDs intrinsically exhibit long operation lifetime and chemical robustness in comparison with OLEDs. Therefore, it is expected that III-nitride μLEDs could potentially replace LCD and OLEDs for high resolution and high brightness display in a wide range of applications in the near future, such as smart phones. In addition to display applications, μLEDs exhibit significantly reduced junction capacitance as a result of reduced dimension compared with broad-area LEDs, and thus potentially lead to high-speed transmission with a GHz modulation bandwidth in VLC applications. Currently, III-nitride μLEDs are exclusively fabricated by means of combining a standard photolithography technique and subsequent dry etching process on a standard III-nitride LED wafer, which is similar to the fabrication of conventional broad-area LEDs with a typical device area of 300 μm×300 μm or even larger dimension. The only major difference in device fabrication between broad-area LEDs and μLEDs is due to device dimension. Typically, the diameter of a μLED ranges from 50 μm down to several micrometres. The current technology is described, for example in: Z. Y. Fan, J. Y. Lin and H. X. Jiang, J. Phys. D: Appl. Phys. 41, 094001 (2008); H. X. Jiang and J. Y. Lin, Optical Express 21, A476 (2013); and J. Day, J. Li, D. Y. C. e C. Bradford, J. Y. Lin and H. X. Jiang, Appl. Phys. Lett. 99, 031116 (2011).

Currently, there exists a major challenge in using current μLEDs for VLC applications, which is due to so-called cross-talk. When a single μLED illuminates, adjacent μLEDs and regions appear illuminated simultaneously, generating cross-talk. For instance, for a multi-channel VLC system using micro-pixelated μLED arrays as transmitters, when a signal is sent down an optical channel from a single μLED, adjacent channels may be carrying the same signal due to optical crosstalk. The mechanisms for the generation of cross-talk are complicated, and are still not very clear. Generally speaking, two major mechanisms have been accepted to be responsible for this cross-talk issue, as described in: H-Y Lin, C-W Sher, D-H Hsieh, X-Y Chen, H-M Philip Chen, T-M Chen, K-M Lau, C-H Chen, C-C Lin, and H-C Kuo, Photonics Research 5, 411 (2017); and K. H. Li, Y. F. Cheung, W. S. Cheung, and H. W. Choi, Appl. Phys. Lett. 107, 171103 (2015). Firstly, the emission mechanism of a μLED is due to spontaneous emission processes, meaning the light emitting from a μLED is distributed over all the directions. The pitch of μLEDs (i.e., pixels) is typically on a scale ranging from a few to 10s of micro-meters. As a result, it is expected that the light emitting from the sidewalls of one μLED has interaction with that from adjacent μLEDs, leading to interference and then cross-talk. Second, even though the sidewalls of all μLEDs in an array configuration are fully covered by an opaque coating, which means that the light emitting from the sidewalls of μLEDs should be completely stopped, the cross-talk issue still exists. This means that there is another channel where the light emitting from one μLED can reach adjacent μLEDs.

III-nitride LEDs are typically grown on sapphire. The refractive index of GaN is larger than 1(the refractive index of air is 1) but is smaller than that of sapphire, naturally forming a waveguide in the GaN layer which is sandwiched between air and sapphire. Due to total internal reflection (TIR) effect, only a small fraction of the emission (about 6%) can be extracted from the GaN surface into air towards the top, while the major part of the rest emission (about 66%) is trapped in the GaN layer by TIR. This is determined by Snell's law. For a μLED array, only a small fraction of the emission gets extracted from the top surface and diverges into an emission cone with a limited solid angle, determined by Snell's law, while beneath the active region, a major portion of the emission emitting downwards from the active region will be confined within the GaN layer under the active region due to TIR. These confined emissions from all the μLEDs will thus channel within the GaN (potentially sapphire as well) which serve as a waveguide. Therefore, the emissions from all the μLEDs will form interaction or interference through the GaN waveguide. This corresponds to the major portion of the emissions from the μLEDs, thus dominating the cross-talk issue.

### SUMMARY OF THE INVENTION

The present invention provides a method of producing a light emitting diode (LED) array, the method comprising: forming a plurality of layers of semiconductor material; forming a dielectric mask layer over the plurality of layers, the dielectric mask layer having an array of holes through it each exposing an area of one of the layers of semiconductor material, and growing an LED structure in each of the holes arranged to emit light over a range of wavelengths, wherein at least some of the plurality layers form a distributed Bragg reflector (DBR) arranged to reflect light of at least some of said range of wavelengths.

At least one of said plurality of layers may form an electrical contact connecting together at least some of the LED structures. The electrical contact may be formed between the DBR and the dielectric layer. The contact layer may be the upper layer of the semiconductor layers. The electrical contact may be formed of a doped semiconductor material, such as an n-doped Group III nitride material, e.g. n-GaN.

Forming the DBR may comprise forming at least 5 pairs of layers, or preferably at least 10 pairs of layers, each pair comprising a first layer of a first material and a second layer of a second material, where the two layers in each pair exhibit different refractive indices. For example, the first and second materials may both comprise Group III nitride materials, but of different compositions, such as different aluminium content, leading to a contrast in refractive index.

One of each pair of layers may be formed of a doped semiconductor material, such as n-GaN, which can be electrochemically etched to into porosity and thus exhibit much lower refractive index than that of GaN. The other of each pair of layers may be formed of un-doped semiconductor material, which remains unaffected during the electrochemical etching process.

The LED structures may be grown on the exposed areas of the upper layer of the semiconductor layers. The growth will generally be in the upward direction, as growth from the dielectric sidewalls of the holes will not occur. The upward growth of the LED structures within the holes may therefore result in a layered LED structure with each of the layers being generally flat or planar, and of substantially constant thickness.

The semiconductor layer may be formed on a substrate, for example of group III nitride, such as GaN, or of sapphire, silicon (Si) silicon carbide (SiC), or of glass.

The step of growing an LED structure in each of the holes may comprise growing an n-type layer. The step of growing an LED structure in each of the holes may comprise growing a prelayer in each of the holes. The step of growing an LED structure in each of the holes may comprise growing at least one active layer in each of the holes. The step of growing an LED structure in each of the holes may comprise growing a p-type layer in each of the holes. The at least one active layer may comprise at least one quantum well layer, and may comprise multiple quantum well layers. These may be formed, for example, of InGaN or another suitable group III nitride material. A prelayer can be, for example, either an InGaN layer with low indium content and a typical thickness of <100 nm or an InGaN/GaN superlattice with low indium content (the total thickness of the superlattice is typically below 300 nm). The n-type and p-type layers may also be of group III nitride material, such as GaN, InGaN or AlGaN.

Because each LED structure is grown in a respective one of the holes, each LED structure is formed of a plurality of layers all having the same cross sectional area, which is equal to the cross sectional area of the hole in which it is grown.

The at least one active layer may have an upper surface which is below the top of the dielectric layer. Where there is only one quantum well layer, the upper surface is the upper surface of that quantum well layer. Where there is a plurality of quantum well layers, the upper surface is the upper surface of the uppermost quantum well layer. The upward direction may be defined as the direction of growth of the semiconductor layer and/or of the LED structures.

The step of forming the dielectric mask layer may comprise growing a layer of dielectric material, and etching the array of holes into the layer of dielectric material. Alternatively the dielectric layer may be grown around the areas which then form the holes, for example using a mask during growth of the dielectric layer.

The method may further comprise etching each of the exposed areas of the semiconductor layer before growing the LED structure in each of the holes.

The contact layer may be doped. For example, it may comprise a single layer of n-type or p-type group III nitride material. Alternatively, the contact layer may comprise first and second sub-layers with a hetero-interface between them arranged to form a two dimensional charge carrier gas at the hetero-interface. The sub-layers may form a buffer layer and a barrier layer. The two dimensional charge carrier gas may, for example, be a two dimensional electron gas (2DEG). A two dimensional hole gas (2DHG) could also be used, but typically these have lower charge carrier density and/or mobility. It is well known that a hetero-structure comprising, for example, a layer of GaN and a layer of AlGaN or InGaN, or more generally two layers of AlGaN with different Al contents or two layers of InGaN with different In contents, can form a 2DEG at the interface between the two layers, with the electron density in the 2DEG varying with a number of factors including the Al content of the AlGaN layer or the In content of the InGaN layer. Other group III nitride hetero-interfaces can be used with the same effect.

The present invention further provides an LED array comprising a plurality of semiconductor layers, a dielectric layer extending over the semiconductor layer and having an array of LED structures extending through it and arranged to emit light over a range of wavelengths, wherein at least some of the plurality layers form a distributed Bragg reflector (DBR) arranged to reflect light of at least some of said range of wavelengths.

The electrical contact layer may be between the DBR and the dielectric layer. This has the advantage that the electrical current powering the LEDs does not flow through the DBR structure, which therefore does not need to be electrically conductive.

The LED array may further comprise an electrode formed on the contact layer.

The method or the LED array may further comprise, in any workable combination, any one or more features of the preferred embodiments of the invention as will now be described with reference to the accompanying drawings.

### BRIEF DESCRIPTION OF THE DRAWINGS

FIG. 1a shows an as-grown template formed in a process according to a first embodiment of the invention;

FIG. 1b shows the template of FIG. 1a with a masking pattern formed in its mask layer;

FIG. 1c shows the template of FIG. 1a with micro-LEDs grown in holes in the mask layer to form an LED array;

FIG. 1d shows the LED array of FIG. 1c with electrical contacts formed on it;

FIG. 2 is a section through an LED structure of the template of the LED array of FIG. 1d;

FIG. 3 is schematic cross section through a DBR forming part of the LED array of FIG. 1d; and

FIG. 4 is a reflectivity curve of the DBR of FIG. 3.

### DETAILED DESCRIPTION

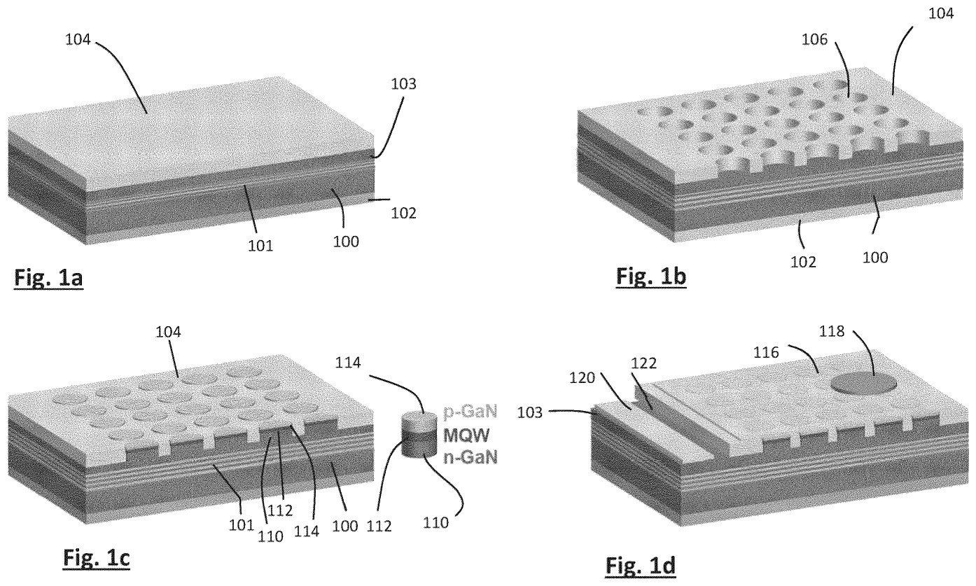

Referring to FIG. 1a, a lower semiconductor layer 100 of group III nitride or other suitable semiconductor, for example a standard un-doped GaN (u-GaN) layer, is initially grown on a substrate 102. The substrate 102 may be a GaN substrate, or may be any foreign substrate such as sapphire, silicon (Si), silicon carbide (SiC) or even glass. The lower semiconductor layer 100 may be grown by means of any standard GaN growth method using either metal-organic vapour phase epitaxy (MOVPE) or molecular beam epitaxy (MBE), or any other suitable growth technique. A plurality of further layers 101 are grown over the lower layer 100. These layers are arranged to form a distributed Bragg reflector (DBR) in which there are alternating layers of two different materials, as will be described in more detail below. An upper semiconductor layer 103 is grown over the DBR layers 101. This layer 103 is arranged to form an electrical contact layer for the LED devices and may for example be of n-type GaN (n-GaN). The contact layer may have a thickness from 50 nm to 10 μm. A dielectric layer 104, such as silicon dioxide (SiO₂) or silicon nitride (SiN), or any other suitable dielectric material, is deposited on the upper semiconductor layer 103 by PECDV or any other suitable deposition technique. The thickness of the dielectric layer may be in the range from 20 nm to 500 μm.

Referring to FIG. 1b, an array of holes 106 is then formed in the dielectric layer 104. The holes 106 are typically on the micrometer scale and therefore referred to as micro-holes. This may be done by means a photolithography technique and then etching processes (which can be dry-etching or wet-etching). In forming the micro-holes 106, the dielectric layer 104 is etched through its entire thickness down to the upper surface of the upper semiconductor layer 103. If the holes 106 are round, they may have diameters from 1 μm to 500 μm, and the pitch distance, i.e. the distance between the centres of adjacent micro-holes, may be, for example, from 5 μm to 500 μm. Further etching, of the upper semiconductor layer 103, only within the micro-hole areas, may be performed using the remained dielectric layer 104 as a mask. The n-GaN etching depth can be from zero (meaning there is no GaN etching) to 10 μm, depending on the n-GaN layer thickness. Typically the optimum etching method or conditions will be different for the upper semiconductor layer 103 than for the dielectric layer 104. For example, SF₆ etchant can be used to etch the dielectric layer 104, but will not etch the n-GaN layer 100. Therefore etching all of the way through the dielectric layer 104 and stopping at the top surface of the upper semiconductor layer 103 is simple to achieve. This also has advantages for the quality of the LED structures grown in the holes 106.

The holes 106 are of a round cross section in the embodiment shown, but other cross sections may be used, for example oval or square.

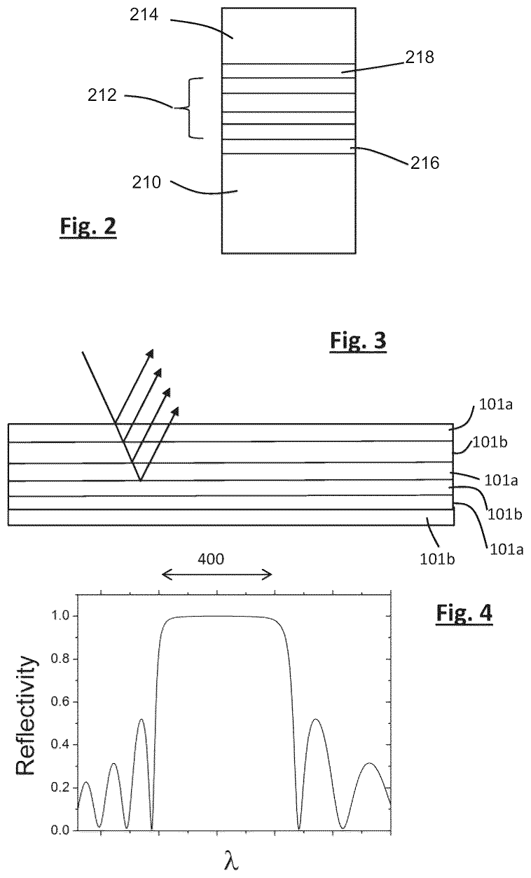

Next, referring to FIG. 1c, a standard III-nitride LED structure is grown on the exposed areas of the upper semiconductor layer 103. However, because only discrete areas of the upper semiconductor layer 103 are exposed by the micro-holes 106 in the dielectric layer or mask, the LED structures are formed as an array of discrete LEDs 108, separated by the remaining parts of the dielectric layer 104 between the micro-holes 106. The LED structures 108 are grown by either MOVPE or MBE techniques, or any other suitable growth technique. The growth occurs upwards from the exposed areas of the GaN (or other semiconductor) of the upper layer 103, and not from the side walls of the holes 106. Therefore the layered LED structure can be built up inside each of the holes 106 with each of the layers being substantially flat or planar. The LED structures may comprise an n-GaN layer 110, an InGaN prelayer, an active region 112, a thin p-type AlGaN layer as a blocking layer (not shown), and then a final p-doped GaN layer 114. The active region 112 may comprise InGaN based multiple quantum wells (MQWs). A prelayer can be, for example, either an InGaN layer with low indium content and a typical thickness of <100 nm or an InGaN/GaN superlattice with low indium content (the total thickness of the superlattice is typically below 300 nm). An example of an LED structure is described in more detail below with reference to FIG. 2. As mentioned above, due to the dielectric mask 104, the LED structures can be grown only within the micro-holes 106, as shown in FIG. 1c, forming a μLED array.

It is important that the uppermost layer of the InGaN MQWs 112 should not extend above the upper surface of the dielectric layer 104, which could result in a short-circuit effect after the template is fabricated into a final μLED array. It is also important that the overgrown n-GaN 110 within each of the micro-hole areas directly contact the upper semiconductor layer 103 within the un-etched parts of the template below the dielectric mask 104 so that all the individual μLEDs are electrically connected to each other through the upper semiconductor layer 103 of the un-etched parts below the dielectric mask 104.

Referring to FIG. 1d, once the LED array structure is completed, further device fabrication is carried out, including the formation of electrical contacts for the array. For example an upper contact layer 116 may be formed over the dielectric mask layer 104 and over the upper p-GaN layer of the individual micro-LED devices 108. The upper contact layer 116 therefore forms a p-contact for all of the LED devices 108. This may be a common p-contact layer for all of the LED devices 108, or may be formed as a plurality of separate areas, cach contacting a respective group of one or more of the LED devices, and having a separate contact formed on it. This allows the LED devices 108 to be switched in groups therefore forming an addressable array. The upper contact layer 116 may be formed of ITO or Ni/Au alloys. An anode 118 may then be formed on the p-contact layer 116. For example, a part of the dielectric layer 104 may be etched away and then the part of the LED structure on the etched dielectric layer section may be also etched down to the upper semiconductor layer 103, exposing an area 122 of the n-GaN upper semiconductor layer 103, and a cathode 120 formed on that exposed area 122 of n-GaN.

In the finished structure as shown in FIG. 1d, light is emitted from each of the LEDs 108 in all directions, but the DBR will reflect light emitted downwards and thereby greatly increase the proportion of light emitted upwards. Generally, a DBR structure shows a very high reflectivity, typically above 90%. Therefore, it will significantly enhance extraction efficiency, meaning that a major part of the emission from individual micro-LEDs will be extracted from the surface, while both the portion of emission emitting from the sidewalls of micro-LEDs and the portion of the emission confined in the GaN as a waveguide under the active region will be reduced or even eliminated in an ideal case. With a proper design (such as by properly designing the layer thickness of the micro-LEDs and the pitch of the micro-LEDs), an extraction efficiency approaching 100% can be obtained due to the photonic crystal effect (refer to Photonic Crystals: Molding the Flow of Light, by J. D. Joannopoulos, R. D. Meade, J. N. Winn, S. G. Johnson, Princeton University Press, 1995) and micro-cavity effect. Cross-talk can therefore be significantly reduced or substantially eliminated.

It will be appreciated that various modifications to the embodiments described above can be made. For example, in one modification the structure is inverted, with a p-GaN layer being grown on the substrate and covered by the dielectric layer, and then the p-GaN layer of the LED devices 108 being formed first, followed by the multiple quantum well layers, and then the n-GaN layer. An n-contact layer is then formed over the top of the dielectric layer in place of the p-contact layer, and the positions of the anode and cathode are reversed.

In the configuration of FIGS. 1a to 1d, the overgrown n-GaN 110 within the micro-holes 106 has to match the n-GaN of the un-etched parts of the n-GaN upper semiconductor layer 103 below the dielectric mask 104 so that all the individual μLEDs 108 are electrically connected to each other through the n-GaN layer 103. Instead of using the n-GaN of the un-etched n-GaN parts below the dielectric mask 104 as an electrically connected channel, in a further embodiment, a Group III nitride heterostructure with a two dimensional electron gas (2 DEG) at the heterojunction is used as the semiconductor layer, instead of the n-GaN layer. In this embodiment a standard AlGaN/GaN HEMT structure is used. The electron gas (2 DEG) with a high sheet carried density and high electron mobility formed at the interface between the AlGaN barrier and the GaN buffer of a high electron mobility transistor (HEMT) structure is used as an electrically connected channel.

In order to produce such a device, a standard AlGaN/GaN HEMT structure is grown over the DBR layers. For example a GaN layer forming a buffer layer may be grown over the DBR layers then an AlGaN layer forming a barrier layer is grown on the GaN layer. This structure is referred to herein as an “as-grown HEMT template”. Subsequently, a dielectric layer such as SiO₂ or SiN or any other dielectric material, for example with a thickness in the range from 2 nm to 500 μm, is deposited on the as-grown HEMT template by using PECVD or any other suitable deposition technique. The resulting structure will be the same as that shown in FIG. 1a, but with the HEMT structure in place of the upper semiconductor layer 103. After that, by means of a photolithography technique and then etching processes (which can be dry-etching or wet-etching) the dielectric layer is etched down to the surface of the HEMT structure to form a micro-hole array in the dielectric layer, where the micro-hole diameter can be from 1 μm to 500 μm, and the pitch distance between adjacent hole centres may be in the range from 5 μm to 500 μm. Further etching the as-grown HEMT within the micro-hole areas can be performed using the remained regions of the dielectric layer as a mask. The as-grown HEMT etching depth can be from zero (meaning there is no any etching) to 10 μm, depending on the AlGaN barrier position of the as-grown HEMT template. However, generally the etching will extend downwards at least as far as the hetero-interface between the two layers of the as-grown HEMT structure, so as to provide good electrical contact between each of the LED structures and the 2 DEG.

Next, a standard III-nitride LED structure is grown on the dielectric mask patterned HEMT template featured with micro-holes by either MOVPE or MBE technique, or any other epitaxy technique, for example as described above with reference to FIG. 1c, and contacts provided, for example as described above with reference to FIG. 1d. As with the embodiment of FIGS. 1a to 1d, an important point is that the upper surface of the InGaN MQWs 212 should be below the upper surface of the dielectric layer 204 so as to avoid a short-circuit effect after being fabricated into final μLED arrays.

Referring to FIG. 2, the LED structures in the LED arrays of FIGS. 1a to 1d may have any suitable structure, but in one example they may include the n-GaN layer 210, an InGaN prelayer 216 formed over the n-GaN layer 210, a number of InGaN quantum well layers 212 formed over the prelayer 216, a p-doped blocking layer 218, for example of p-AlGaN, and then the p-GaN layer 214. It will be appreciated that this structure can be varied in a number of ways. As indicated above, it is preferable that the top of the uppermost one of the quantum well layers 212 is below the top of the dielectric layer. It is also preferable that the top of the blocking layer 218 is also below the top of the dielectric layer.

Referring to FIG. 3, as described above, the DBR layers 101 comprise alternating layers 101a, 101b, of two different materials having different refractive indices, so that light from the LEDs is reflected at the interfaces between the layers 101. The principles of DBRs are well known so will not be described in detail, but the layers 101a, 101b are of approximately equal thickness, and the thickness is approximately one quarter of the wavelength of the light (in the material of the DBR layers) that is to be reflected so as to produce constructive interference of reflected light and destructive interference of transmitted light.

The DBR structure 101 may be based on an Al(Ga)N/GaN system, meaning a number of pairs of alternating Al(Ga)N and GaN layers grown by MOVPE or MBE or any other growth techniques. The DBR structure may alternatively comprise a number of pairs of alternating GaN and nanoporous GaN layers. In order to produce this structure, a number of pairs of alternating n-doped GaN and un-doped GaN layers can be prepared by MOVPE or MBE or any other growth techniques, and a standard electrochemical (EC) etching is then conducted. The mechanism of EC etching is based on a combination of an oxidation process and then a dissolution process in acidic solution under an anodic bias as described in Y. Hou, Z. Ahmed Syed, L. Jiu, J. Bai, and T. Wang, Appl. Phys. Lett. 111, 203901 (2017). Under a positive anodic bias, the injection current will flow through the n-doped GaN part which is conductive leading to the oxidation of n-doped GaN, and the oxidized layer is then chemically dissolved in an acidic electrolyte, converting the n-doped GaN into nanoporous GaN. Therefore, EC etching can be performed on n-type GaN only, due to its good conductivity, while un-doped GaN which is not conductive remains un-etched.

Referring to FIG. 4, the reflectivity of a DBR is a function of wavelength, but typically a DBR can be arranged to have a relatively broad range of wavelengths, the stopband 400, over which almost total reflection is achieved. For either the Al(Ga)N/GaN DBR or the GaN and nanoporous GaN DBR, the stopband can be tuned to cover a wide spectral range, from infra-red, through the whole visible, to ultra-violet. The reflectivity is also a function of the angle of incidence of the light on the DBR, but in the LED arrays described above, the main function of the DBR is to reflect light emitted downwards through 180° back in an upward direction so the DBR can be designed to achieve that.

The reflectivity of a DBR increases with the number of pairs of layers 101a, 101b. Therefore, the DBR structure may have at least 5 pairs of layers, and more preferably at least 10 pairs of layers.

The LEDs 108 will each emit light over a range of wavelengths. That range of wavelengths can be selected by selecting, among other things, the cross sectional area of the LEDs 108. For example, it has been shown that LEDs grown as described above have a peak wavelength in the red part of the spectrum if their diameter is about 30 μm, in the green part of the spectrum if their diameter is about 20 μm, and in the blue part of the spectrum if their diameter is about 10 μm. If the LEDs all have the same electro-luminescence spectrum, then the DBR can be arranged to have a stopband centred on, or at least including, the peak wavelength of the LEDs. If the LEDs are designed to have different electro-luminescence spectra. with different peak wavelengths. then the DBR can be optimised to provide the best overall reflectivity for the different LEDs.

1. A method comprising:
forming a distributed Bragg reflector (DBR) arranged to reflect light of at least some of a range of wavelengths;
forming an upper semiconductor layer over the DBR;
forming a dielectric layer over the upper semiconductor layer, the dielectric layer having an array of holes through it, each hole of the array of holes exposing a respective area of the upper semiconductor layer; and
in each hole of the array of holes:
growing an LED structure arranged to emit light over the range of wavelengths, the LED structure comprising an active region that does not extend above an upper surface of the dielectric layer.

2. The method of claim 1, wherein:
the upper semiconductor layer forms an electrical contact electrically connecting two or more of the LED structures.

3. The method of claim 2, wherein:
the upper semiconductor layer is formed of a doped semiconductor material.

4. The method of claim 3, wherein:
the upper semiconductor layer comprises a gallium nitride material.

5. The method of claim 4, wherein:
the upper semiconductor layer comprises a p-type gallium nitride material or an n-type gallium nitride material;
each of the LED structures comprises a gallium nitride material layer formed in contact with the upper semiconductor layer; and
the gallium nitride material layer of each of the LED structures has a same conductance type as the upper semiconductor layer.

6. The method of claim 1, wherein:
the DBR comprises at least two pairs of layers of semiconductor material, each of the pairs comprising a first layer of a first material and a second layer of a second material.

7. The method of claim 6, wherein:
one of the layers of each of the pairs of layers is formed of a doped semiconductor material and is electrochemically etched to increase its porosity.

8. The method of claim 7, wherein:
another of the layers of each of the pairs of layers is formed of un-doped semiconductor material.

9. An LED array comprising:
a distributed Bragg reflector (DBR) arranged to reflect light of at least some of a range of wavelengths;
an upper semiconductor layer over the DBR;
a dielectric layer extending over the upper semiconductor layer, an array of holes being defined through the dielectric layer, each hole of the array of holes exposing a respective area of the upper semiconductor layer; and
in each hole of the array of holes:
an LED structure arranged to emit light over the range of wavelengths, the LED structure comprising an active region that does not extend above an upper surface of the dielectric layer.

10. The LED array of claim 9, wherein:
the upper semiconductor layer forms an electrical contact electrically connecting two or more of the LED structures.

11. The LED array of claim 10, wherein:
the upper semiconductor layer is formed of a doped semiconductor material.

12. The LED array of claim 10, further comprising:
an electrode formed on the upper semiconductor layer.

13. The LED array of claim 10, wherein:
each of the LED structures contacts the upper semiconductor layer.

14. The LED array of claim 9, wherein:
the upper semiconductor layer comprises a gallium nitride material.

15. The LED array of claim 14, wherein:
each of the LED structures comprises a gallium nitride material layer formed in contact with the upper semiconductor layer.

16. The LED array of claim 15, wherein:
the upper semiconductor layer comprises a p-type gallium nitride material or an n-type gallium nitride material; and
the gallium nitride material layer of each of the LED structures has a same conductance type as the upper semiconductor layer.

17. The LED array of claim 9, wherein:
the DBR comprises at least two pairs of layers of semiconductor material, each of the pairs comprising a first layer of a first material and a second layer of a second material.

18. The LED array of claim 17, wherein:
one of the layers of each of the pairs of layers is formed of a doped semiconductor material and is electrochemically etched to increase its porosity.

19. The LED array of claim 18, wherein:
another of the layers of each of the pairs of layers is formed of un-doped semiconductor material.

20. An array of light-emitting means comprising:
reflecting means to reflect light of at least some of a range of wavelengths;
an upper semiconductor layer over the reflecting means;
an insulating layer extending over the upper semiconductor layer, an array of holes being defined through the insulating layer, each hole of the array of holes exposing a respective area of the upper semiconductor layer; and
in each hole of the array of holes:
a light-emitting means arranged to emit light over the range of wavelengths, the light-emitting means comprising a light-emitting region that does not extend above an upper surface of the insulating layer.
